(19) United States
(12) Patent Application Publication
(10) Pub. No.: US 2006/0250148 A1
(43) Pub. Date: Nov. 9, 2006

(54) Probe card support plate

(75) Inventor: Kelly S. Daughtry, Burleson, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/120,856

(22) Filed: May 3, 2005

(51) Int. Cl. G01R 31/02

(52) U.S. Cl. 324/754

(57) ABSTRACT

According to one embodiment of the present invention a an apparatus for probing a wafer includes a probe card, a support plate, and at least one probe needle. At least a portion of the support plate is formed from a ceramic material comprising alumina. The at least one probe needle in communication with the probe card.

### TECHNICAL FIELD OF THE INVENTION

This invention relates in general to testing of electronic components, and more particularly to a probe card support plate.

### BACKGROUND OF THE INVENTION

An array of die, which may include integrated circuits and their components, are typically supported on a wafer during various semiconductor fabrication processes. At various stages during fabrication processes, it may be desirable to perform testing on each die to read information from each die, write information to each die, or otherwise gather information about each die and components on each die.

### SUMMARY OF THE INVENTION

According to one embodiment of the present invention a an apparatus for probing a wafer includes a probe card, a support plate, and at least one probe needle. At least a portion of the support plate is formed from a ceramic material comprising alumina. The at least one probe needle in communication with the probe card.

Certain embodiments may provide a number of technical advantages. For example, a technical advantage of one embodiment may include the capability to give a probe card the needed stability to probe wafers at higher temperatures without causing a damage to the equipment or production. Other technical advantages of other embodiments may include the capability to provide a structure that will aid in reducing probe card needle wear, reducing bond damage, reducing probe setup problems, reducing delays in customer orders, and/or increasing wafer throughput.

Although specific advantages have been enumerated above, various embodiments may include all, some, or none of the enumerated advantages. Additionally, other technical advantages may become readily apparent to one of ordinary skill in the art after review of the following figures, description, and claims.

### BRIEF DESCRIPTION OF THE DRAWINGS

To provide a more complete understanding of the present invention and features and advantages thereof, reference is made to the following description, taken in conjunction with the accompanying figures, wherein like reference numerals represent like parts, in which:

FIG. 1 illustrates a side cut-away cross sectional view of a portion of a tester;

FIGS. 2A and 2B illustrate comparisons of probe card deflections measured at 30 degrees Celsius and 120 degrees Celsius, respectively;

FIGS. 3A and 3B are a table 550 and a graph 650, illustrating comparisons of a probe card and probe card support plate movement (in microns) measured at 125 degrees Celsius.

### DETAILED DESCRIPTION OF EXAMPLE EMBODIMENTS

It should be understood at the outset that although example implementations of embodiments of the invention are illustrated below, the present invention may be implemented using any number of techniques, whether currently known or in existence. The present invention should in no way be limited to the example implementations, drawings, and techniques illustrated below. Additionally, the drawings are not necessarily drawn to scale.

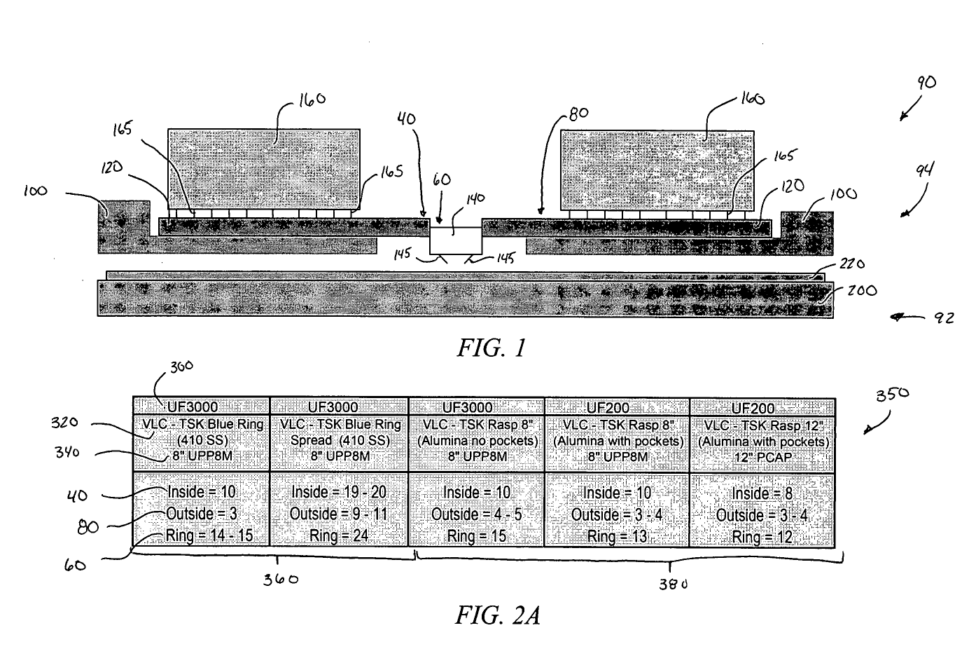

FIG. 1 illustrates a side cut-away cross sectional view of a portion of a wafer tester 90. The illustrated portion of the tester 90 of FIG. 1 may be utilized to perform operations on a wafer 220, such as testing of one or more die that may be positioned on the wafer 220. The wafer tester 90 in this embodiment includes a lower tester portion 92 with a chuck 200 supporting wafer 220 and an upper tester portion 94 with a probe card 120, a pogo stack 160, pogo pins 165, a ring 140, probe needles 145, and a probe card support plate 100.

The probe card 120 may be take on a variety of configurations (e.g., circular, square, or the like) depending on the particular wafer 220 being tested. The probe card 120 in this embodiment is shown resting on and supported by the probe card support plate 100. The ring 140, coupled to the probe card 120, may hold the probe needles 145 on the probe card 120 and can be made of a ceramic material or other suitable material. The pogo stack 160 is shown sitting on top of the probe card 120. The pogo stacks 160 may be in communication with a test head, although not explicitly shown. In operation, the pogo stack 160 receives information from the test head and communicates such information to the probe card 120 via the pogo pins 165.

Although one configuration of the illustrated portion of the wafer tester 90 has been shown in FIG. 1, it will be understood by one of ordinary skill in the art that the configuration of the wafer tester 90 may be varied significantly, or alternatively substituted with any suitable components or elements that are utilized to perform operations on a wafer 220. Further, although specific components are shown in the embodiment of FIG. 1, other embodiments may utilize some or none of the components shown herein.

The operation of a wafer tester 90 and various alternative configurations thereof will be recognized by one of ordinary skill in the art. Amongst the processes involved in these operations, the chuck 200 may move the wafer 220 into contact with the probe needles 145 to perform testing of one or more die (not explicitly shown) on the wafer 220, to read information from the one or more die, to write information to the one or more die, to perform other suitable operations on the wafer 220, or to engage in combinations of the preceding. During this process, the chuck 200 generates thermal energy and may transfer at least a portion of this thermal energy to the probe needles 145, ring 140, probe card 120, and probe card support plate 100. Additionally, a force of the upward movement of the chuck 200 may be imparted through the wafer 220 to the probe needles 145, ring 140, probe card 120, and probe card support plate 100. Such force, alone, or in combination with the increased thermal energy may undesirably cause portions of the upper tester portion 94 to move as described in further detail below. For example, the inside portion of the upper test portion 94 may bow up. Such undesirable movement may damage the upper tester portion 94, the wafer 220, and/or reduce yield in testing. As one example, fifty microns of “over travel” on the probe needles 145 may cause the probe needles 145 to bend or damage. As another example, movement of the probe card support plate by 140 microns may cause the probe card 120 to crash. Such undesirable movement may be exacerbated through a cooling process that follows a heating process of the portion of the wafer tester 90, resulting in expansion and contraction that may occur in various components of the wafer tester.

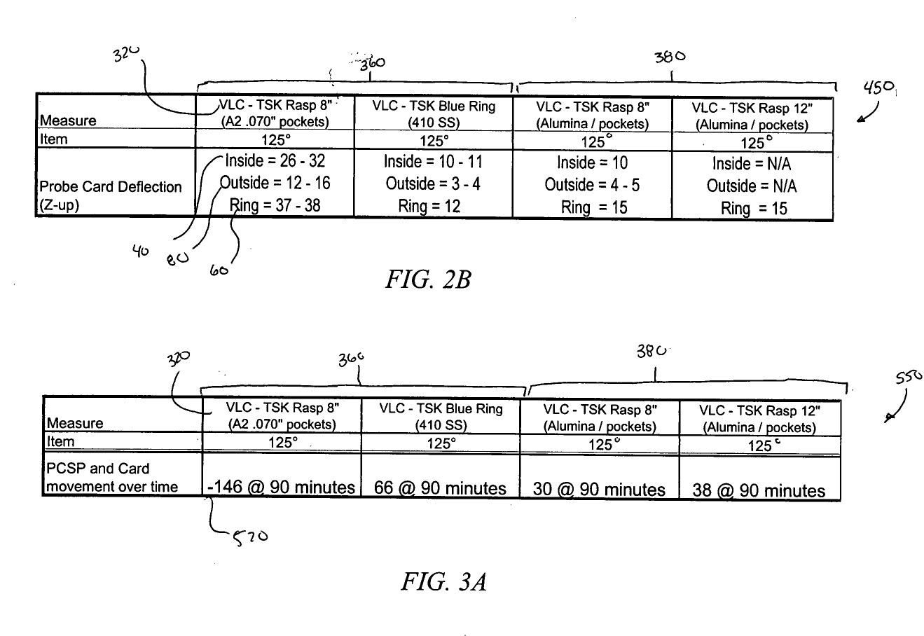

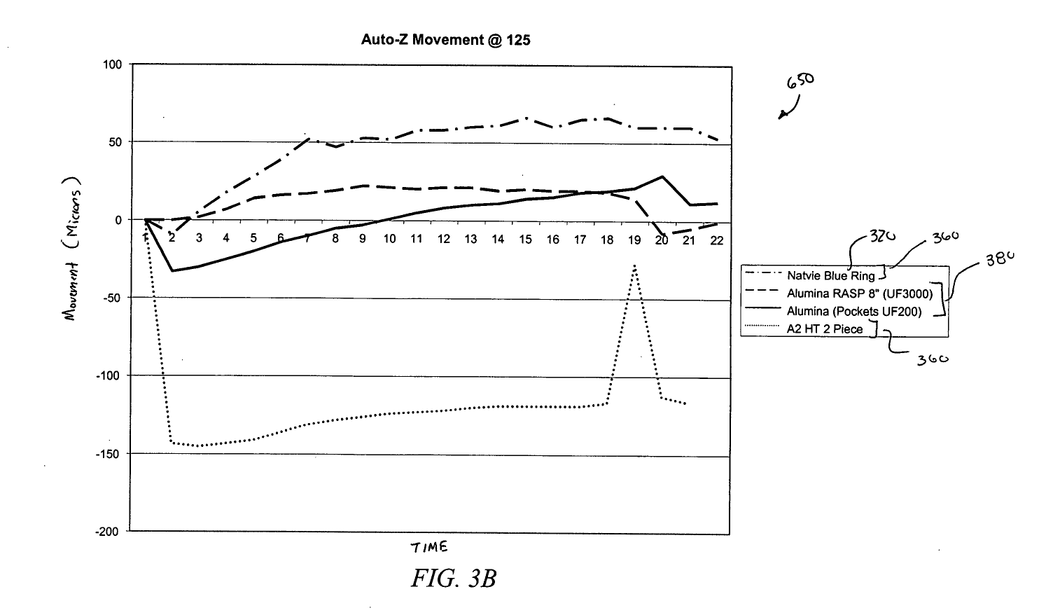

Teachings of embodiments of this invention recognize that the probe card support plate 100 begins to lose desirable support properties as the probe card support plate 100 receives thermal energy. Traditional support plates are made of a variety of metallic materials. One example metallic material is 410 Stainless Steel. 410 Stainless Steel has a coefficient of thermal expansion of approximately eleven micrometers/meter-degrees Celsius. 410 Stainless Steel has a modulus of elasticity (also referred to as Young's modulus) of 200 GigaPascals (GPa). Teachings of embodiments of this invention recognize that ideally the material utilized in the probe card support plate needs to be resistant to thermal change (e.g., during heat up and cool down), strong enough to support a force of the pogo pins 165, and stable enough to hold the probe card 120, ring 140, and needles 145 in a stable condition during testing on the wafer 220. To improve upon the characteristics of traditional support plates, teaching of embodiments of this invention recognize that other materials may be utilized in the probe card support plate 100. According to one embodiment of the invention, the probe card support plate 100 may be made of a composite ceramic having alumina (also referred to as aluminum oxide). In other embodiments, the probe card support plate may be made of ceramic composites that do not have alumina. In embodiments utilizing ceramic composites have alumina, a variety of different percentages of alumina may be utilized including, but not limited to, between 80% alumina by weight and 99.9% alumina by weight. As an example, a ceramic composite having 99.5% alumina by weight has a coefficient of thermal expansion of approximately 6.9 micrometers/meter-degrees Celsius and a modulus of elasticity of 210 GigaPascals (GPa). Although ranges of alumina have been given above, other alumina percentages may be utilized in other embodiments, for example, greater than 99.9% by weight alumina or less than 80% alumina by weight. Comparisons of traditional materials against materials of embodiments of the invention are illustrated below with reference to FIGS. 2A, 2B, 3A, and 3B.

FIGS. 2A and 2B show tables 350, 450 illustrating comparisons of probe card deflections measured at 30 degrees Celsius and 120 degrees Celsius, respectively. Measurement were taken using a 0.00005 inch indicator at various locations on the upper tester portion 94, namely an inside measurement 40, a ring measurement 60, and an outside measurement 80. The location of all three measurements 40, 60, and 80 seen in FIG. 1. Group 360 of tables 350, 450 are conventional materials and group 380 are ceramic composites having 95.5% alumina by weight. The measurements 40, 60, and 80 represent upward deflections (Z-up) in microns. For measurements 40, 60, and 80, table 350 of FIG. 2A includes the needle type 300, the probe card support plate type 320, and the probe card type 340. For measurements 40, 60, and 80, table 450 of FIG. 2B includes the probe card support plate type 320 and the probe card type 340. As illustrated, the measurements 40, 60, and 80 for group 380 are at least as good as or better than the measurements 40, 60, and 80 for group 360.

FIGS. 3A and 3B are a table 550 and a graph 650, illustrating comparisons of a probe card and probe card support plate movement (in microns) measured at 125 degrees Celsius. Similar to FIGS. 2A and 2B, the table 550 and graph 650 include the probe card type 320 and the table 550 includes groups 360, 380. The table 550 of FIG. 3A includes a maximum deflection 520 as measured over a 90 minute interval. The chart 650 of FIG. 3B plots movement (in microns) of the probe card support plate type 320 shown in FIG. 3A over a 90 minute time period. As can be seen with reference to FIGS. 3A and 3B, deflections are minimized with group 380 ceramic materials as compared to group 360 traditional materials.

Numerous other changes, substitutions, variations, alterations, and modifications may be ascertained to one skilled in the art and it is intended that the present invention encompass all such changes, substitutions, variations, alterations, and modifications as falling within the scope of the appended claims.

What is claimed is:

1. An apparatus for probing a wafer, the apparatus comprising:
a support plate, at least a portion of the support plate being formed from a ceramic material, the at least a portion of the support plate having greater than eighty percent alumina by weight, and the at least a portion of the support plate having a modulus of elasticity greater than 210 GigaPascals, and the at least a portion of the support plate having a coefficient of thermal expansion less than 10 micro-meter/meter-degrees Celsius;
a probe card supported by the ceramic composite support plate;
a pogo stack in communication with the probe card;
a ceramic ring coupled to the probe card; and
at least one probe needle coupled to the ceramic ring and in communication with the probe card.

2. The apparatus of claim 1, wherein
the at least a portion of the support plate has greater than ninety-nine percent alumina by weight,
the at least a portion of the support plate has a modulus of elasticity greater than 300 GigaPascals, and
the at least a portion of the support plate has a coefficient of thermal expansion less than 8 micro-meter/meter-degrees Celsius.

3. An apparatus for probing a wafer, the apparatus comprising:
a probe card;
a support plate for supporting the probe card, at least a portion of the support plate being formed from a ceramic material; and
at least one probe needle in communication with the probe card.

4. The apparatus of claim 3, wherein
the at least a portion of the support plate comprises alumina.

5. The apparatus of claim 4, wherein
the at least a portion of the support plate comprises greater than ninety percent alumina by weight.

6. The apparatus of claim 4, wherein
the at least a portion of the support plate has a coefficient of thermal expansion less than 10 micro-meter/meter-degrees Celsius.

7. The apparatus of claim 4, wherein
the at least a portion of the support plate has a modulus of elasticity greater than 210 GigaPascals.

8. The apparatus of claim 7, wherein
the at least a portion of the support plate has greater than ninety percent alumina by weight, and
the ceramic composite support plate has a modulus of elasticity greater than 300 GigaPascals.

9. The apparatus of claim 7, wherein
the at least a portion of the support plate has a coefficient of thermal expansion less than 10 micro-meter/meter-degrees Celsius.

10. The apparatus of claim 3, wherein
the at least a portion of the support plate has a modulus of elasticity greater than 210 GigaPascals

11. The apparatus of claim 10, wherein
the at least a portion of the support plate has a coefficient of thermal expansion less than 10 micro-meter/meter-degrees Celsius.

12. The apparatus of claim 3, wherein
the at least a portion of the support plate has a coefficient of thermal expansion less than 10 micro-meter/meter-degrees Celsius.

13. An apparatus for probing a wafer, the apparatus comprising:
a probe card; and
a support plate, at least of a portion of the support plate made of a material having a coefficient of thermal expansion less than 10 micro-meter/meter-degrees Celsius; and
at least one probe needle in communication with the probe card.

14. The apparatus of claim 13, wherein
the at least of a portion of the support plate has a modulus of elasticity greater than 210 GigaPascals.

15. The apparatus of claim 14, wherein
the at least of a portion of the support plate has a modulus of elasticity greater than 300 GigaPascals.

16. The apparatus of claim 13, wherein
the at least of a portion of the support plate comprises alumina.

17. The apparatus of claim 16, wherein
the at least of a portion of the support plate has greater than ninety percent alumina by weight.

18. The apparatus of claim 16, wherein
the at least of a portion of the support plate has a coefficient of thermal expansion less than 8 micro-meter/meter-degrees Celsius.

19. The apparatus of claim 16, wherein
the support plate has a modulus of elasticity greater than 210 GigaPascals.

20. The apparatus of claim 19, wherein
the at least of a portion of the support plate has greater than ninety percent alumina by weight,
the support plate has a modulus of elasticity greater than 300 GigaPascals, and
the support plate has a coefficient of thermal expansion less than 8 micro-meter/meter-degrees Celsius.
